(19) United States
(12) Patent Application Publication
(10) Pub. No.: US 2025/0141423 A1
(43) Pub. Date: May 1, 2025

(54) ACOUSTIC WAVE DEVICE WITH ENHANCED QUALITY FACTOR

(71) Applicant: RichWave Technology Corp., Taipei City (TW)

(72) Inventor: Shih-Meng Lin, Taipei City (TW)

(73) Assignee: RichWave Technology Corp., Taipei City (TW)

(21) Appl. No.: 18/519,084

(22) Filed: Nov. 27, 2023

(30) Foreign Application Priority Data
Oct. 30, 2023 (TW) 112141527

(51) Int. Cl. H03H 9/02; H03H 9/13; H03H 9/17

(52) U.S. Cl. CPC H03H 9/02118; H03H 9/02157; H03H 9/132; H03H 9/173; H03H 9/175

(57) ABSTRACT

An acoustic wave device includes a first electrode, a piezoelectric layer and a second electrode. The piezoelectric layer is disposed at least partially on the first electrode. The second electrode is disposed at least partially on the piezoelectric layer. The second electrode includes an electrode body having an outline and a plurality of protrusions extending from the outline of the electrode body. The two ends of two adjacent ones of the plurality of protrusions are separated by a gap and the gap exposes at least a portion of the piezoelectric layer.

### TECHNICAL FIELD

The present invention relates to the field of acoustic wave technology, and in particular, to an acoustic wave device.

### BACKGROUND

Bulk acoustic waves (BAW) devices may be used to convert and transceive electrical signals and/or acoustic signals. The BAW devices may be widely applicable to fields such as electrical communications, global positioning system (GPS), and military uses. The BAW devices may be used to configure BAW filters, which may filter out noises from wireless signals so as to achieve a desired band of frequency and result in advantages such as lower transmission loss, stronger ability to avoid interference from electromagnetic, and/or a compact size. In addition, SAW devices may also be implemented in resonators. A BAW device may generate a spurious mode, which may cause undesirable energy leakage and performance degradation.

### SUMMARY

According to an embodiment of the invention, an acoustic wave device includes a first electrode, a piezoelectric layer and a second electrode. The piezoelectric layer is disposed at least partially on the first electrode. The second electrode is disposed at least partially on the piezoelectric layer. The second electrode includes an electrode body having an outline and a plurality of protrusions extending from the outline of the electrode body. The two ends of two adjacent ones of the plurality of protrusions are separated by a gap and the gap exposes at least a portion of the piezoelectric layer.

### BRIEF DESCRIPTION OF THE DRAWINGS

FIG. 1 is a schematic diagram of an acoustic wave device according to an embodiment of the invention.

FIG. 2 to FIG. 8 are schematic diagrams of various acoustic wave devices according to various embodiments of the invention.

FIG. 9 is a schematic cross-sectional view of an acoustic wave device along section line 9-9′ shown in FIG. 1 according to an embodiment of the invention.

FIG. 10 is a schematic cross-sectional view of an acoustic wave device along section line 9-9′ in FIG. 1 according to another embodiment of the invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

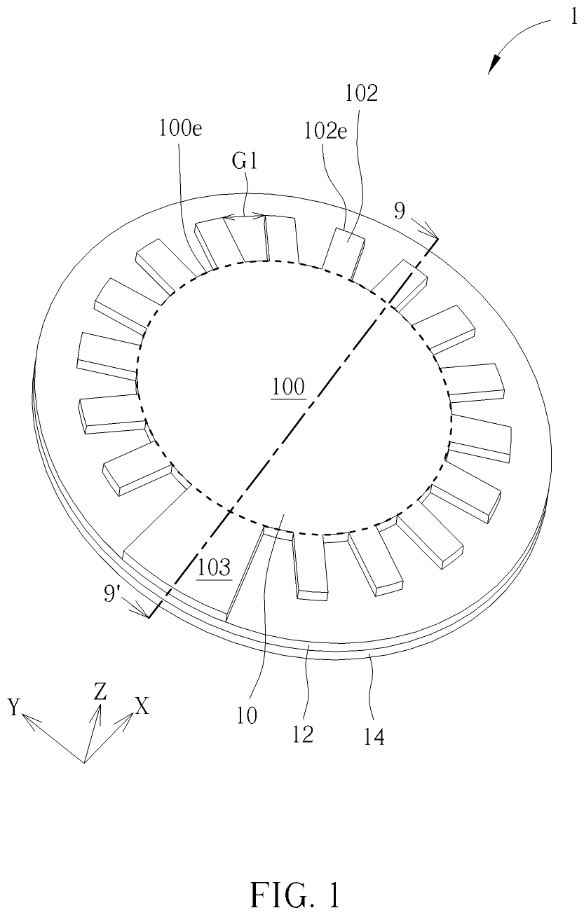

FIG. 1 is a schematic diagram of an acoustic wave device 1 according to an embodiment of the invention. The acoustic wave device 1 may include a bulk acoustic wave (BAW) device, and may implemented for a resonator, a filter or other radio frequency devices. In some embodiments, the acoustic wave device 1 may be used for a BAW resonator, which may be configured to receive an input signal, generate an acoustic wave, and convert the acoustic wave into a resonant signal. In other embodiments, the acoustic wave device 1 may be implemented for a BAW filter, which may be configured to receive an input signal from e.g., an antenna, filter the received signal based on a frequency selectivity, and allow signals with desired frequencies to pass. Various applications of the acoustic wave device 1 may be provided above for illustrative description without limiting.

In some embodiments, the acoustic wave device 1 may include an electrode 10, a piezoelectric layer 12 and an electrode 14. In FIG. 1, the electrode 10 may be for example an upper electrode, and the electrode 14 may be for example a lower electrode. The piezoelectric layer 12 may be disposed at least partially on the electrode 10, and the electrode 14 may be disposed at least partially on the piezoelectric layer 12. As shown, an overlapped area of the electrode 10, the piezoelectric layer 12, and the electrode 14 may be referred to as an active area, and in the active area, acoustic waves may propagate along direction Z. For example, the material of the electrodes 10 and/or 14 may include conductive materials such as molybdenum (Mo), copper (Cu), aluminum (Al), gold (Au), platinum (Pt), tungsten (W), other suitable metals or a combination thereof. The material of the piezoelectric layer 12 may include, for example, at least one of the followings: zinc oxide (ZnO), aluminum nitride (AlN), lithium tantalate (LiTaO₃, LT), lithium niobate (LN), quartz (QZ), lead titanate (PTO), lead zirconate titanate (PZT), other materials or a combination thereof. In some embodiments, the piezoelectric layer 12 may be doped with a rare earth element such as scandium (Sc).

In operation, the electrode 10 may be used to receive an input signal, and the electrode 14 may be grounded to generate an acoustic wave propagating along a vertical direction Z. The piezoelectric layer 12 may be used to convert the acoustic wave into a resonant signal with a resonant frequency. The resonant frequency may be determined depending on various parameters of the acoustic wave device 1, such as the material and/or thickness of the piezoelectric layer 12, the weights of the electrode 10 and/or the electrode 14, etc. For example, the resonant frequency may range from 100 megahertz (MHz) to 20 gigahertz (GHz). The material of the substrate may include silicon, glass, ceramic, gallium arsenide, and/or silicon carbide.

In the embodiment, the piezoelectric layer 12 may be located on the electrode 14, and the electrode 10 may be located on the piezoelectric layer 12. The piezoelectric layer 12 and the electrode 14 may have, but are not limited to, the same shape (such as a circle) and dimensions. In some embodiments, the piezoelectric layer 12 and the electrode 14 may have different shapes or dimensions. For example, the area of the piezoelectric layer 12 (across the X-Y plane) may be larger than that of the electrode 14.

In FIG. 1, the electrode 10 may include an electrode body 100 and a plurality of protrusions 102. The electrode body 100 has an outline 100e indicated by a dotted line, and the plurality of protrusions 102 may extend from the outline 100e of the electrode body 100, for example, extending from the outline 100e to the end 102e of one of the protrusions 102. Any of the plurality of protrusions 102 are electrically connected to the electrode body 100. In some embodiments, two ends of two adjacent ones of the plurality of protrusions 102 are separated by a gap G1, and the gap G1 may expose the piezoelectric layer 12 beneath, for example, exposing at least a portion of the piezoelectric layer 12. The protrusions 102 may not be used for connecting, that is, the protrusions 102 may not be connected between the electrode body 100 and other conductive elements. With respect to the electrode body 100, the plurality of protrusions 102 may form a slow zone for an acoustic wave around the periphery of the electrode body 100, and the slow zone may be used to confine as much energy as possible within the area of electrode body 100, so as to achieve a reduced energy leakage. Therefore, a spurious mode may be suppressed and the quality factor of the acoustic wave device 1 may be enhanced. In some embodiments, the end 102e of one protrusion 102 may not contact or connect with the end 102e of another protrusion 102.

In some embodiments, the acoustic wave device 1 may further include a connection 103 that is electrically connected to the electrode 10. The connection 103 may be used to connect the electrode 10 with other conductive components. For example, the connection 103 may be disposed at the outline 100e of the electrode body 100 of the electrode 10, and may electrically connect the electrode body 100 to an external solder pad and/or solder ball for signal transceiving.

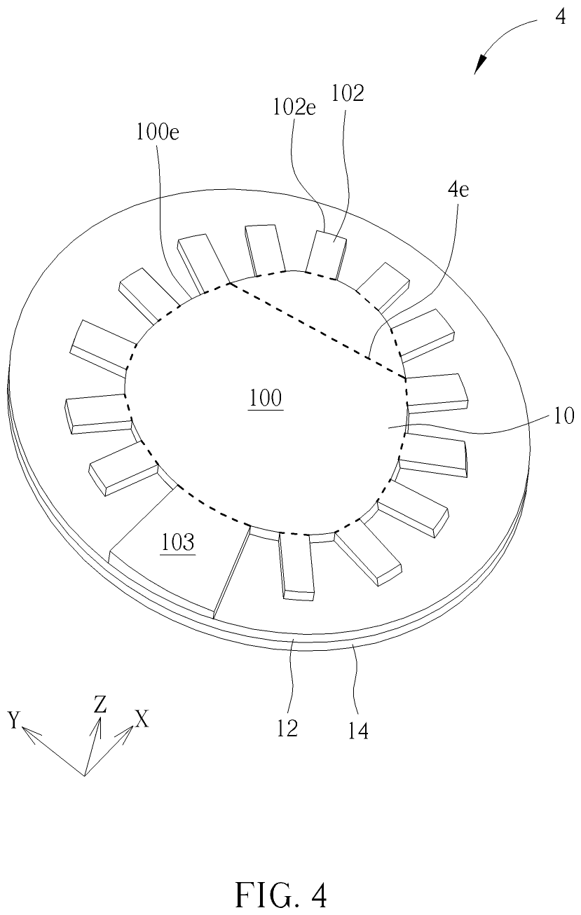

In some embodiments, the shape of the outline 100e of the electrode body 100 may be for example selected from the followings: a polygonal shape, a circular shape, an elliptical shape, an egg shape, or a truncated egg shape, such as those shown in FIG. 1 and FIG. 4. FIG. 1 shows that the electrode body 100 has a circular outline 100e, and FIG. 4 shows that the electrode body 100 of the acoustic wave device 4 has an egg-shaped or truncated egg-shaped outline 100e. In FIG. 4, the egg-shaped outline 100e may include a flatter wide portion and a sharper narrow portion. The straight line 4e may be cut through two side portions between the wide portion and the narrow portion, and may be, for example, closer to the narrow portion relative to the wide portion. The straight line 4e with the wide portion together may form a truncated egg-shaped outline.

In some embodiments, the material of the protrusions 102 may include a conductive material identical to that of the electrode body 100, such as molybdenum, and the protrusions 102 may be monolithically integrated with the electrode body 100. For example, the protrusions 102 and the electrode body 100 may be formed with the material of Mo and by ways of the same process step. In other embodiments, the material of the plurality of protrusions 102 may be different from the material of the electrode 100. For example, the material of the plurality of protrusions 102 may be W, and the material of the electrode 100 may be Mo. In other embodiments, the material of the protrusions 102 may include a non-conductive material, such as ceramic, glass, metal oxide and other suitable dielectric materials.

In the acoustic wave device 1, each of the plurality of protrusions 102 may have a substantially rectangular outline. It should be noted that the rectangular outline may not be a perfectly defined rectangle, that is, four sides of the outline of the protrusion 102 may not all be straight lines. Specifically, in case that the electrode body 100 may have a circular outline 100e, one protrusion 102 may contact the outline 100e at one side of the protrusion 102, and this side of the protrusion 102 may conform to the shape of the outline 100e and may thus be arc-shaped.

In some embodiments, at least one of the plurality of protrusions 102 may have a following outline: a rectangle, a square, an arc, a circle, a triangle, a trapezoid, or a polygon as shown in FIG. 1 to FIG. 3.

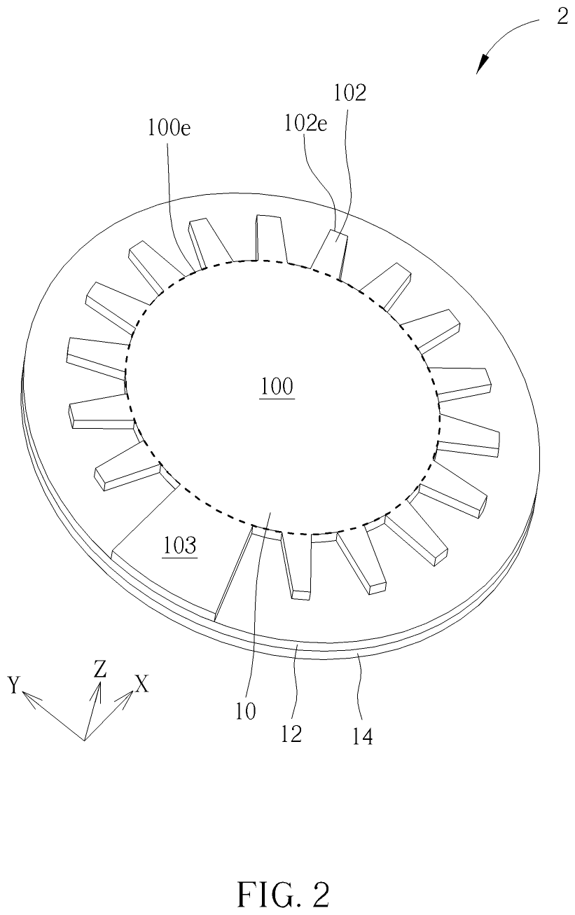

In the acoustic wave device 2 in FIG. 2, each of the plurality of protrusions 102 may have a substantially trapezoidal outline, including a long side contacting the electrode body 100, two lateral sides, and a short side farther away from the electrode body 100. The long side of the trapezoidal outline may be curved and the short side may be straight. In some alternative embodiments, the positions of the long side and the short side may be interchanged. In other words, the protrusion 102 may include a short side contacting the electrode body 100, two lateral sides, and a long side farther away from the electrode body 100.

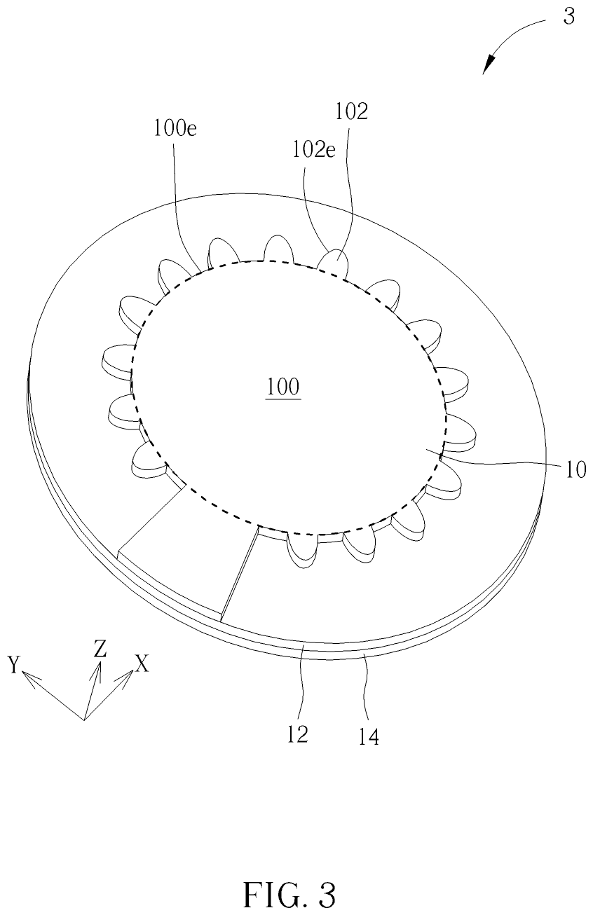

In the acoustic wave device 3 in FIG. 3, each of the plurality of protrusions 102 may have a substantially curved outline. In other embodiments, a protrusion 102 may have a substantially triangular outline, which includes an apex, two sides and a curved bottom side, and the curved bottom side may contact the outline 100e of the electrode body 100. Alternatively, the apex of the triangular outline may be configured to contact the outline 100e of the electrode body 100.

Although each of the plurality of protrusions 102 may have the same outline in the acoustic wave devices in FIG. 1-FIG. 3, the invention is not limited thereto. Those skilled in the art would recognize that in other embodiments, the plurality of protrusions 102 may not necessarily have the same outline shape, for example, they may include a first one with a rectangular outline and a second one with a trapezoidal outline.

In some embodiments, the plurality of protrusions 102 may be evenly distributed along the outline 100e of the electrode body 100. However, the present invention is not limited thereto. In other embodiments, the plurality of protrusions 102 may be unevenly distributed along the outline 100e. In one case, the plurality of protrusions 102 may be distributed merely along a portion of the outline 100e. Specifically, such as in FIG. 1, the plurality of protrusions 102 may be evenly distributed along most of the outline 100e and unevenly distributed near the connection 103.

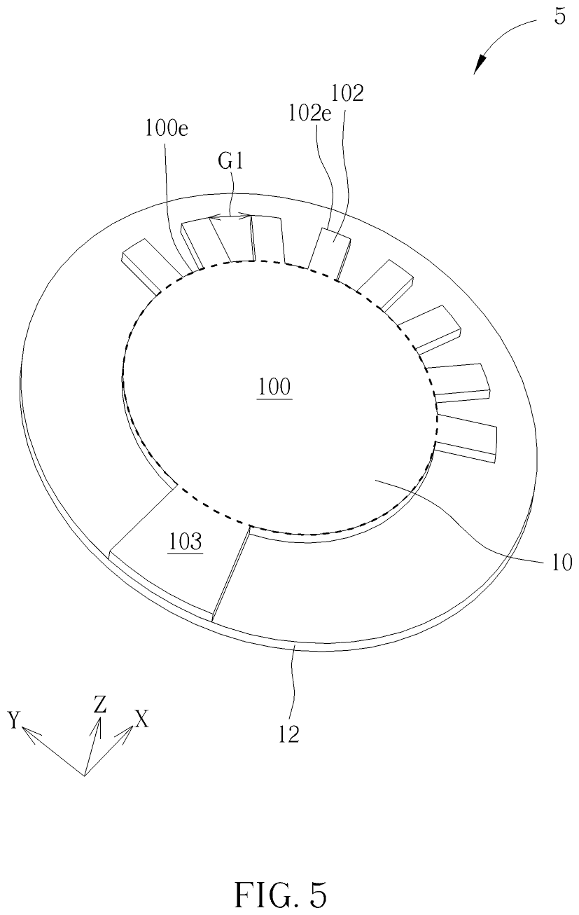

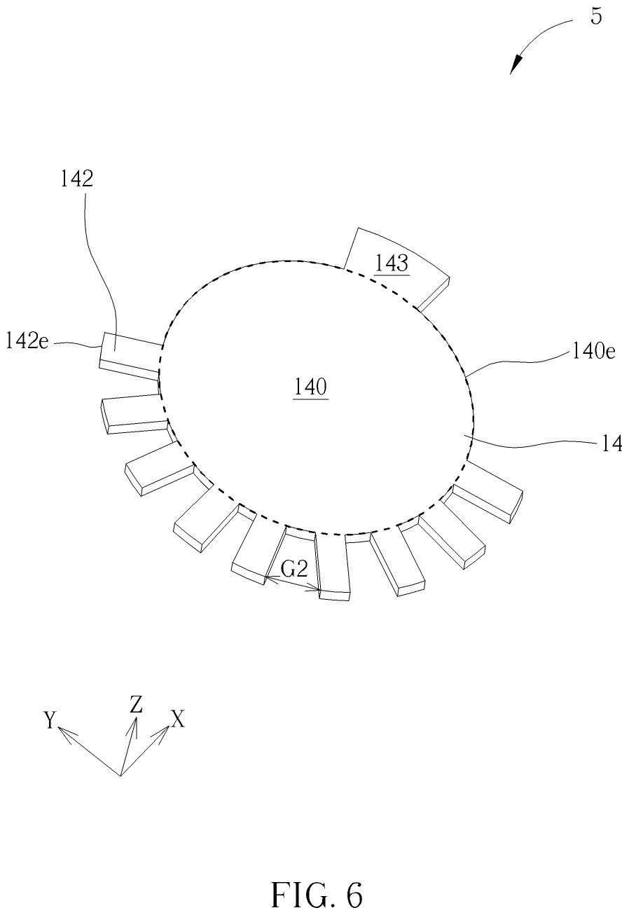

FIG. 5 and FIG. 6 are respectively schematic diagrams of the shapes of the electrodes 10 and 14 according to another embodiment of the invention. The electrodes 10 and 14 of the acoustic wave device 4 may be used to replace the electrodes 10 and 14 of the acoustic wave device 1 respectively. The structures of the electrode 10 in FIG. 5 and the electrode 14 in FIG. 6 will be explained in greater detail below. The electrode 10 and the piezoelectric layer 12 are shown in FIG. 5, and the electrode 14 is shown in FIG. 6.

In FIG. 5, the electrode 10 of the acoustic wave device 5 may include an electrode body 100 having an outline 100e and a plurality of protrusions 102 extending from the outline 100e. The plurality of protrusions 102 may be distributed merely along a portion of the outline 100e (for example, half of the circle), and may be evenly distributed across this portion. In this case, a gap G1 is separated between two ends of two adjacent protrusions 102, and the gap G1 may expose the piezoelectric layer 12 beneath. In other embodiments, the plurality of protrusions 102 may be unevenly distributed along this portion of the outline 100e. In the embodiment, the plurality of protrusions 102 may form a slow zone (for example, a first slow zone) for the acoustic waves around the periphery of the electrode body 100. Therefore, a spurious mode may be suppressed.

In FIG. 6, the electrode 14 of the acoustic wave device 5 may include an electrode body 140 having an outline 140e and plurality of protrusions 142 extending from the outline 140e. The plurality of protrusions 142 may be distributed merely along a portion of the outline 140e (for example, half of the circle), and may be evenly distributed along this portion. In such a case, a gap G2 is separated between two ends of two adjacent protrusions 142. In other embodiments, the plurality of protrusions 142 may be unevenly distributed along a portion of the outline 100e. In the embodiment, the plurality of protrusions 142 may form a slow zone (for example, a second slow zone) for the acoustic waves around the periphery of the electrode body 140, and thus a spurious mode may be suppressed. The shapes of the outline and configurations of the plurality of protrusions 142 may be similar to those of the plurality of protrusions 102, and the explanations therefor may be omitted here for brevity.

In some embodiments, the electrode 12 and the piezoelectric layer 14 shown in FIG. 5 may be used together with the electrode 14 shown in FIG. 6. For example, the electrode 12 and the piezoelectric layer 14 in FIG. 5 may be located on the electrode 14 in FIG. 6 along the direction Z, and thus the plurality of protrusions 102 of the electrode 12 and the plurality of protrusions 142 of the electrode 14 may be non-overlapped along the direction Z. In the embodiment, the electrode body 100 of the electrode 12, the piezoelectric layer 12, and the electrode body 140 of the electrode 14 may be partially overlapped along the direction Z, so as to form an active area corresponding to the overlapped area. Preferably, when projecting onto the X-Y plane, the first slow zone formed by the plurality of protrusions 102 and the second slow zone formed by the plurality of protrusions 142 may be non-overlapped, or further, may be partially overlapped, so that more energy of the acoustic wave may be confined within the active area, thereby enhancing the quality factor of the acoustic wave device.

In other embodiments, when projecting onto the X-Y plane, the plurality of protrusions 102 and the plurality of protrusions 142 may be distributed to alternate with each other. For example, the projection of a protrusion 102 on the X-Y plane may correspond to the gap G2 between two adjacent protrusions 142. Similarly, the projection of a protrusion 142 on the X-Y plane may correspond to the gap G1 between two adjacent protrusions 102, so that more energy of the acoustic wave may be confined within the active area, thereby enhancing the quality factor of the acoustic wave device.

In FIG. 5, a connection 103 may be further included, and it may be configured, e.g., at the outline 100e of the electrode body 100 to be connected between the electrode 10 (specifically, the electrode body 100) and other conductive components. In FIG. 6, a connection 143 may be further included, and it may be configured, e.g., at the outline 140e of the electrode body 140 to be connected between the electrode 14 (specifically, the electrode body 140) and other conductive components, and the conductive component may be such as an external solder pad and/or solder ball. When projecting along the direction Z, the connection 103 and the connection 143 may be non-overlapped, or partially overlapped.

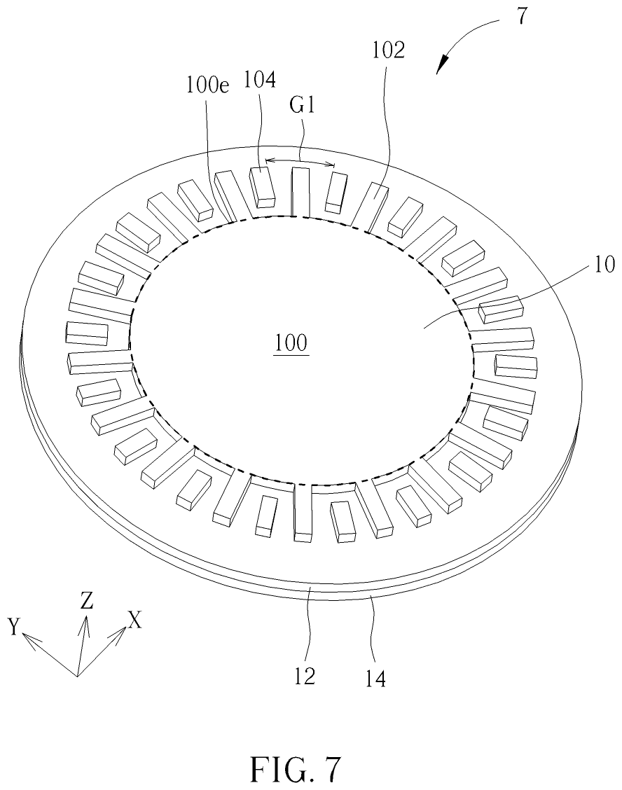

FIG. 7 is a schematic diagram of an acoustic wave device 7 according to an embodiment of the invention. The acoustic wave device 7 and the acoustic wave device 1 are substantially different in that the acoustic wave device 7 may further include at least one barrier 104. The barriers 104 of the acoustic wave device 7 will be explained in detail below.

As shown in FIG. 7 the acoustic wave device 7 may include an electrode 10, a piezoelectric layer 12 and an electrode 14. The electrode 10 may include an electrode body 100 and a plurality of protrusions 102. The electrode body 100 has an outline 100e (indicated by the dotted line), and the plurality of protrusions 102 may extend from the outline 100e of the electrode body 100. In some embodiments, the acoustic wave device 7 may further include at least one barrier 104 disposed on the piezoelectric layer 12 and may located in the gap G1 between two adjacent protrusions 102. A barrier 104 may be electrically disconnected from the electrode body 100. Specifically, the barrier 104 may not contact the electrode body 100, and may be separated from the outline 100e of the electrode body 100 by spacing. The outline of the barrier 104 may be rectangular, square, arc-shaped, triangular, trapezoidal, or polygonal. In the illustrated embodiment, each barrier 104 has a rectangular outline.

For example, the material of the barrier 104 includes a conductive material or a non-conductive material, and the material of the barrier 104 may be identical to or different from the material of the electrode body 100. In one embodiment, the material of the barrier 104 may be identical to the material of the electrode body 100, and may further be identical to the material of the protrusion 102, such as molybdenum. In such a case, the electrode body 100, the protrusions 102, and the barriers 104 may be formed of molybdenum during the same process. In another embodiment, the material of the barrier 104 may be different from the material of the electrode body 100, or further different from the material of the protrusion 102. For example, the material of the electrode body 100 may be molybdenum, the material of the protrusion 102 may also be molybdenum, and the material of the barrier 104 may be tungsten. In other embodiments, the material of the protrusion 102 may include a non-conductive material, for example, the material of the barrier 104 may be a dielectric material such as ceramic, glass, metal oxide, and others. It should be noted that a connection 103 may be omitted from FIG. 7.

In above embodiments, the at least one barrier 104 may be configured to enhance the slow zone formed by the protrusion 102 around the periphery of the electrode body 100. Therefore, a spurious mode may be further suppressed and the quality factor of the acoustic wave device 7 may be further enhanced.

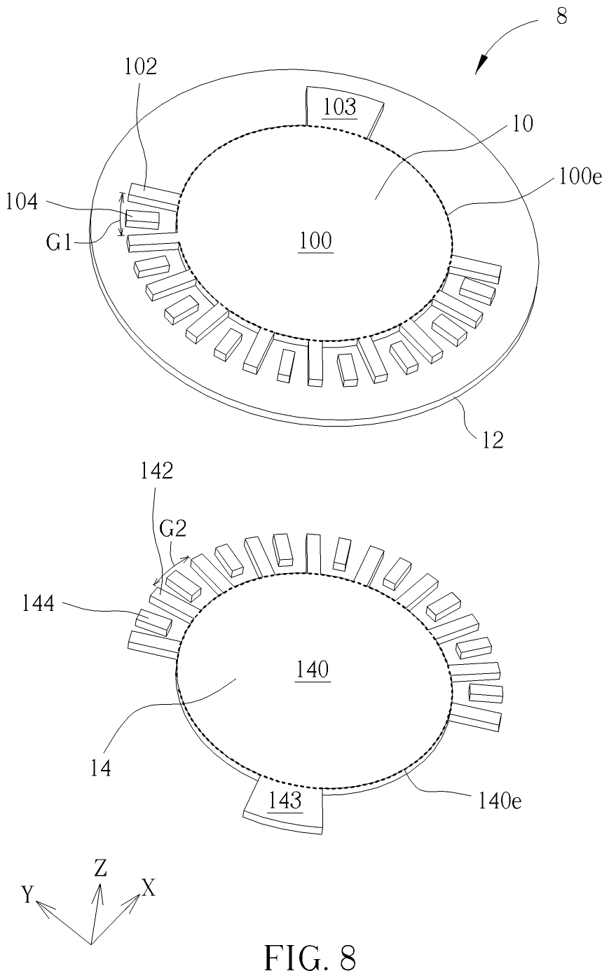

FIG. 8 is a schematic diagram of an acoustic wave device 8 according to another embodiment of the invention. The acoustic wave device 8 and the acoustic wave device 5 are substantially different in that the acoustic wave device 8 may further include at least one barrier 104 and at least one barrier 144. The barriers 104 and the barriers 144 of the acoustic wave device 8 will be explained in more detail below. It should be noted that in FIG. 8, the electrode 10, the piezoelectric layer 12, and the electrode 14 are shown separately.

As for electrode 10, each barrier 104 is shown to be disposed on the piezoelectric layer 12 and located in a gap G1 between two adjacent protrusions 102 of the electrode 10. In some embodiments, a barrier 104 may be electrically disconnected from the electrode body 100. As for electrode 14, each barrier 144 is shown to be disposed in a gap G2 between two adjacent protrusions 142 of the electrode 14. In some embodiments, a barrier 144 may be electrically disconnected from the electrode body 140.

The barriers 104 of the acoustic wave device 8 are similar to the barriers 104 of the acoustic wave device 7, and the explanation therefor will not be repeated here. The barriers 144 and the barriers 104 of the acoustic wave device 8 are substantially different in that the barriers 144 are disposed for the electrode 14 (e.g., the lower electrode) and the barriers 104 are disposed for the electrode 10 (e.g., the upper electrode). Similarly, the material of the barriers 144 may be selected similarly to the barrier 104, and may be e.g. a conductive material or a non-conductive material, and will not be explained here for brevity. In some embodiments, the outline of the barrier 144 may have a rectangular, square, arc, triangular, trapezoidal, or polygonal shape. In the illustrated embodiment, each barrier 144 has a rectangular outline.

In the above embodiments, taking the electrode 10 (e.g., the upper electrode) as an example, the electrode body 100 may have a maximum dimension on the X-Y plane, and the protrusion 102 may also have a maximum dimension on the X-Y plane. In FIG. 1, the maximum dimension of the electrode body 100 may be defined by the diameter of the circular outline 100e, and the maximum dimension of the protrusion 102 may be defined by the distance from the outline 100e to the end 102e of the protrusion 102 along a radial direction. In some embodiments, the ratio of the maximum dimension of the protrusion 102 to the maximum dimension of the electrode body 100 may be between 0.05 and 1.0, and for example, the ratio may be 0.1. It should be appreciated that the definition of the maximum dimension of the electrode body 100 or the protrusion 102 may not such limited. For example, in the case where the electrode body 100 or the protrusion 102 has a polygonal outline, the maximum dimension of the electrode body 100 or the protrusion 102 may be defined by the longest diagonal of the polygon outline. In the case where the electrode body 100 or the protrusion 102 has an egg-shaped outline, the maximum dimension of the electrode body 100 or the protrusion 102 may be defined by the maximum distance from the wide portion to the narrow portion.

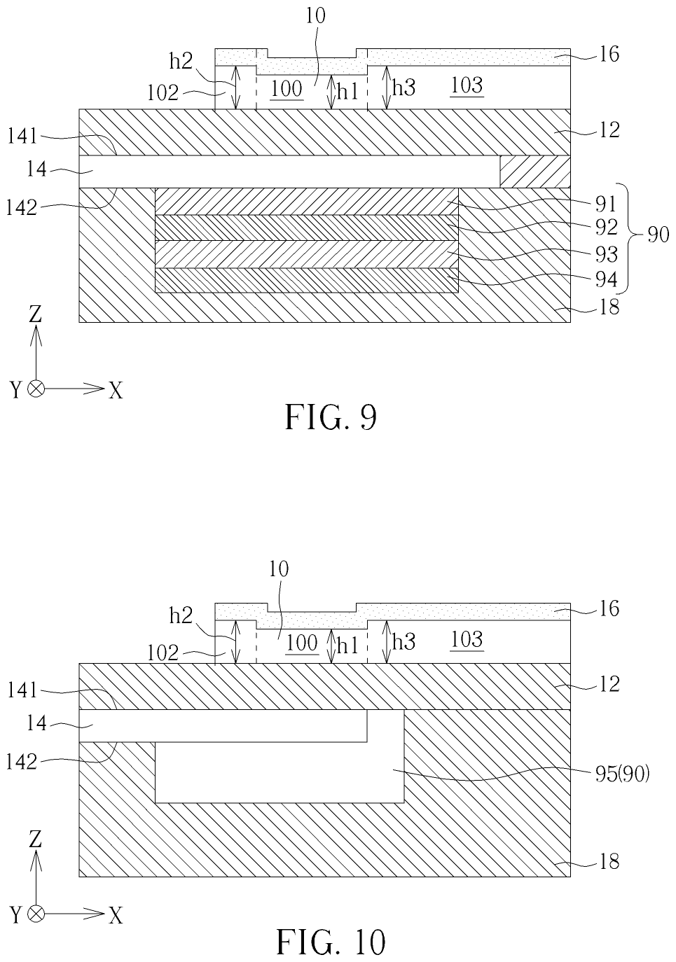

FIG. 9 is a schematic cross-sectional view of an acoustic wave device along section line 9-9′ shown in FIG. 1 according to an embodiment of the invention. The acoustic wave device may include, for example, a substrate 18, an electrode 14, a piezoelectric layer 12, an electrode 10, and a passivation layer 16 stacked in sequence. Specifically, the passivation layer 16 may be disposed on the electrode 10, and may cover at least the electrode body 100, the protrusions 102 and the connection 103, thereby protecting the acoustic wave device 1. For example, the material of the passivation layer 16 may include silicon oxide (e.g., silicon dioxide) or silicon nitride.

The electrode 14 may include a surface 141 (e.g., an upper surface of the electrode 14) and a surface 142 (e.g., a lower surface of the electrode 14). The substrate 18 is disposed at the surface 142 of the electrode 14, and the piezoelectric layer 12 is disposed at the surface 141 of the electrode 14.

As shown, the substrate 18 may include a reflector 90 that may be disposed in the substrate 14, such that the reflector 90, the electrode 14, the piezoelectric layer 12, and the electrode 10 are at least partially overlapped along the direction Z. The reflector 90 may include, for example, a plurality of stacked layers such as stacked layers 91 to 94. In the example, the stacked layers 91 to 94 may have different acoustic impedances, so as to form a Bragg reflector, which may be used to reduce the leakage of acoustic waves. The number of stacked layers is merely used for illustration but is not used to limit the invention.

In FIG. 9, the electrode body 100 may have a thickness h1 in the direction Z, the protrusion 102 may have a thickness h2 in the direction Z, and the thickness h2 may be greater than or equal to the thickness h1. It should be noted that the electrode 10 may include a plurality of protrusions 102, and they may have identical or different thicknesses. For example, the plurality of protrusions 102 may include one with a thickness h21 and another with a thickness h22, and the thickness h21 may be different from the thickness h22. Furthermore, the thickness h21 may be greater than the thickness h1 of the electrode body 100, and the thickness h22 may be less than the thickness h1 of the electrode body 100. In the above embodiment, various protrusions of different thicknesses are beneficial to forming an enhanced slow zone for the acoustic waves around the periphery of the electrode body 100. Specifically, thicker protrusions may be used to form additional weight loads around the periphery of the electrode body 100, further confining more energy within the area of the electrode body 100.

In addition, FIG. 9 also shows that the connection 103 has a thickness h3, and the thickness h3 exceeds the thickness h1 of the electrode body 100. However, the present invention is not such limited, and in other embodiments, the thickness h3 of the connection 103 may also be equal to or less than the thickness h1 of the electrode body 100.

FIG. 10 is a schematic cross-sectional view of an acoustic wave device along section line 9-9′ in FIG. 1 according to another embodiment of the invention. FIG. 10 and FIG. 9 are substantially different in that the reflector 90 may include an air cavity 95 in FIG. 10 rather than the stacked layers 91 to 94 in FIG. 9.

The acoustic wave device shown in any of FIG. 1 to FIG. 10 may employ the configuration of the plurality of protrusions and/or the barriers, so as to form a slow zone surrounding the electrode body. The slow zone may be used to confine as much energy as possible within the area of electrode body, and thus a reduced energy leakage may be achieved. Therefore, a spurious mode may be suppressed and the quality factor of the acoustic wave device may be enhanced.

Those skilled in the art will readily observe that numerous modifications and alterations of the device and method may be made while retaining the teachings of the invention. Accordingly, the above disclosure should be construed as limited merely by the metes and bounds of the appended claims.

What is claimed is:

1. An acoustic wave device comprising:
a first electrode;
a piezoelectric layer disposed at least partially on the first electrode; and
a second electrode disposed at least partially on the piezoelectric layer, the second electrode comprising:
a second electrode body having a second outline; and
a plurality of second protrusions extending from the second outline of the second electrode body, wherein two ends of two adjacent ones of the plurality of second protrusions are separated by a second gap, and the second gap exposes at least a portion of the piezoelectric layer.

2. The acoustic wave device of claim 1, wherein a material of one of the plurality of second protrusions is different from a material of the second electrode body.

3. The acoustic wave device of claim 1, wherein a thickness of one of the plurality of second protrusions in a vertical direction exceeds a thickness of the second electrode body in the vertical direction.

4. The acoustic wave device of claim 1, wherein a ratio of a maximum dimension of one of the plurality of second protrusions on a horizontal plane and a maximum dimension of the second electrode body on the horizontal plane is between 0.05 and 1.0.

5. The acoustic wave device of claim 1, wherein the plurality of second protrusions are evenly distributed along at least a portion of the second outline of the second electrode body.

6. The acoustic wave device of claim 1, wherein the plurality of second protrusions are unevenly distributed along at least a portion of the second outline of the second electrode body.

7. The acoustic wave device of claim 1, wherein one of the plurality of second protrusions has an outline of a shape selecting from the followings: a rectangle, a square, an arc, a triangle, a trapezoid, or a polygon.

8. The acoustic wave device of claim 7, wherein one of the plurality of second protrusions has a trapezoidal outline comprising a short side, two lateral sides, and a long side;
wherein the short side contacts the second outline of the second electrode body; or
the long side contacts the second outline of the second electrode body.

9. The acoustic wave device of claim 1, further comprising a barrier disposed on the piezoelectric layer and located in the second gap between the two adjacent ones of the plurality of second protrusions.

10. The acoustic wave device of claim 9, wherein the barrier is electrically disconnected from the second electrode body.

11. The acoustic wave device of claim 9, wherein a material of the barrier is different from a material of the second electrode body.

12. The acoustic wave device of claim 9, wherein the barrier has an outline of a shape selecting from the followings: a rectangle, a square, an arc, a triangle, a trapezoid, or a polygon.

13. The acoustic wave device of claim 1, wherein the second outline of the second electrode body has a shape selecting from the followings: a polygon, a circle, an ellipse, an egg, or a truncated egg.

14. The acoustic wave device of claim 1, wherein the second electrode further comprises:
a second connection disposed at the second outline of the second electrode body and electrically connected to the second electrode body.

15. The acoustic wave device of claim 14, wherein the first electrode comprises:
a first electrode body having a first outline; and
a plurality of first protrusions extending from the first outline of the first electrode body, wherein two ends of two adjacent ones of the plurality of first protrusions are separated by a first gap; and
the plurality of second protrusions and the plurality of first protrusions are at least partially non-overlapped in a vertical direction.

16. The acoustic wave device of claim 15, wherein the first electrode further comprises:
a first connection disposed at the first outline of the first electrode body and electrically connected to the first electrode body;
wherein the second connection and the first connection are at least partially non-overlapped in a vertical direction.

17. The acoustic wave device of claim 15, wherein:
the plurality of second protrusions are distributed along a portion of the second outline;
the plurality of first protrusions are distributed along a portion of the first outline; and
the portion of the second outline and the portion of the first outline are non-overlapped along the vertical direction.

18. The acoustic wave device of claim 1, wherein:
the first electrode comprises a first surface and a second surface, and the piezoelectric layer is disposed at the second surface of the first electrode; and
the acoustic wave device further comprises a substrate disposed at the first surface of the first electrode.

19. The acoustic wave device of claim 18, wherein the substrate comprises a reflector in the substrate, and the reflector, the first electrode, the piezoelectric layer, and the second electrode are at least partially overlapped in a vertical direction.

20. The acoustic wave device of claim 19, wherein the reflector comprises an air cavity and/or a plurality of stacked layers.
